(19) United States
(12) Patent Application Publication
(10) Pub. No.: US 2023/0188112 A1
(43) Pub. Date: Jun. 15, 2023

(54) COMPOSITE SUBSTRATE OF FILTER, METHOD FOR MAKING COMPOSITE SUBSTRATE OF FILTER, AND TEMPERATURE COMPENSATED SURFACE ACOUSTIC WAVE FILTER

(71) Applicant: FUJIAN JING'AN OPTOELECTRONICS CO., LTD., Quanzhou City (CN)

(72) Inventors: Yenfu LIN, Quanzhou City (CN); Zhonghe LIN, Quanzhou City (CN); Shengyu YANG, Quanzhou City (CN); Minghui FANG, Quanzhou City (CN); Shihwei HUANG, Quanzhou City (CN)

(73) Assignee: FUJIAN JING'AN OPTOELECTRONICS CO., LTD., Quanzhou City (CN)

(21) Appl. No.: 18/167,702

(22) Filed: Feb. 10, 2023

Related U.S. Application Data
(63) Continuation-in-part of application No. PCT/CN2021/115877, filed on Sep. 1, 2021.

(51) Int. Cl. H03H 9/02; H03H 3/08; H03H 9/64; H10N 30/072

(52) U.S. Cl. CPC H03H 9/02574; H03H 3/08; H03H 9/64; H03H 9/02834; H10N 30/072

(57) ABSTRACT

A method for making a composite substrate of a filter includes: processing a base substrate to form a centrally protruding structure having a height that decreases in a radially outward direction from a center of the base substrate to an outer periphery of the base substrate; connecting a first side of the base substrate having the centrally protruding structure to a piezoelectric layer so as to obtain a multilayer substrate; and thinning the piezoelectric layer of the multilayer substrate followed by polishing a surface of the piezoelectric layer.

### CROSS-REFERENCE TO RELATED APPLICATION

This application is a bypass continuation-in-part (CIP) application of PCT International Application No. PCT/CN2021/115877 filed on Sep. 1, 2021. The entire content of the international patent application is incorporated herein by reference.

### FIELD

The disclosure relates to a filter, and more particularly to a composite substrate of a filter, a method for manufacturing the same, and a temperature compensated surface acoustic wave (TC-SAW) filter.

### BACKGROUND

Conventional surface acoustic wave (SAW) filters are difficult to meet requirements of radio frequency (RF) terminal in a fifth generation (5G) communication system that has an increasingly crowded band because they have low quality factor (Q) (e.g., lower than 1000) and a frequency drifting with a change of working temperature. Therefore, the conventional SAW filters require to develop toward SAW filters that have a high frequency and a stable temperature property (e.g., a temperature compensated surface acoustic wave (TC-SAW) filter). The SAW filters are easily affected by the change of the working temperature, i.e., when the ambient temperature increases, a material for substrates of the SAW filters tends to have a smaller rigidity, and a sound speed of the SAW filters may be reduced, so that the frequency of the SAW filters drifts with the change of the ambient temperature. Currently, a composite substrate is used in the TC-SAW filter and is formed by (i) connecting a piezoelectric layer (e.g., a lithium niobate (LN) chip or a lithium tantalate (LT) chip) to a substrate (made of one of spinel, polycrystalline sapphire, monocrystalline sapphire, and silicon) under high vacuum and high pressure and at room temperature, and (ii) subsequently thinning the piezoelectric layer using thinning and polishing techniques, so as to form the composite substrate of the TC-SAW filter. The thinned piezoelectric layer may have a thickness ranging from 15 µm to 30 µm. By virtue of the aforesaid composite substrate, the TC-SAW filter might have a high quality factor (Q), a low temperature coefficient of frequency (TCF), and an improved performance.

With development of the communication system having a high frequency, the thickness of the piezoelectric layer of the TC-SAW filter reduces accordingly. When the thickness of the piezoelectric layer is smaller than 5 µm, the piezoelectric layer may have a huge thickness variation due to the problems of difficult processing. As shown in FIG. 1, after being subjected to a thinning process, the piezoelectric layer has an obvious thickness variation (ranging from 2.5 µm to 3.4 µm), and the performance of the TC-SAW filter may be adversely affected due to such thickness variation of the piezoelectric layer. Therefore, a thickness uniformity of the piezoelectric layer of the TC-SAW filter has started to receive attention.

The thickness variation of the piezoelectric layer of the conventional TC-SAW filter may range from about 20% to about 40%. For example, if a predetermined thickness of the piezoelectric layer of the conventional TC-SAW filter is 3 µm, and an actual thickness thereof will range from 2.1 µm to 3.6 µm. That is to say, the actual thickness of the piezoelectric layer ranges from 70% to 120% of the predetermined thickness of the piezoelectric layer, and therefore the thickness variation of the piezoelectric layer ranges from 20% to 30%. In such case, 900 MHz TC-SAW filter may have a frequency drift value greater than 1000 ppm (parts per million) and 1800 MHz TC-SAW filter may have a frequency drift value greater than 2000 ppm, resulting in a poor yield of the TC-SAW filter.

Therefore, there is a need to improve the thickness uniformity of the piezoelectric layer.

### SUMMARY

Therefore, an object of the disclosure is to provide a method for making a composite substrate of a filter that can alleviate at least one of the drawbacks of the prior art.

According to a first aspect of the disclosure, a method for making a composite substrate of a filter including the steps of:
a) processing a base substrate to form a centrally protruding structure having a height that decreases in a radially outward direction from a center of the base substrate to an outer periphery of the base substrate;
b) connecting a first side of the base substrate having the centrally protruding structure to a piezoelectric layer so as to obtain a multilayer substrate; and
c) thinning the piezoelectric layer of the multilayer substrate, followed by polishing a surface of the piezoelectric layer.

According to a second aspect of the disclosure, a composite substrate of a filter is manufactured by the aforesaid method.

According to a third aspect of the disclosure, a temperature compensated surface acoustic wave (TC-SAW) filter includes the aforesaid composite substrate of the filter and a fork-finger transducer disposed on the composite substrate of the filter. The piezoelectric layer of the composite substrate has a thickness variation smaller than 10%.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 shows a thickness distribution of a piezoelectric layer that is made of lithium tantalate (LiTaO₃) and that is made through a conventional processing technique.

FIG. 2 is a schematic view illustrating a conventional temperature compensated surface acoustic wave (TC-SAW) filter.

FIG. 3 shows schematic side views illustrating the consecutive steps of a method for making a composite substrate of the TC-SAW filter of FIG. 2.

FIG. 4 is a functional flow chart illustrating consecutive steps of a method for making a composite substrate of a filter according to a first embodiment of the disclosure.

FIG. 5 is a pictorial drawing illustrating the consecutive steps of the method of FIG. 4.

FIG. 6 is a schematic cross-sectional view illustrating an example of a base substrate used in the composite substrate of the filter according to the disclosure.

FIG. 7A is a schematic view illustrating different polishing pad regions of an adjustable air cushion polishing machine.

FIG. 7B is a schematic cross-sectional view of FIG. 7A.

FIG. 8 shows a morphology of a base substrate in a comparative example.

FIG. 9 shows a thickness distribution of a piezoelectric layer made of lithium tantalate in the comparative example.

FIG. 10 shows a thickness distribution of a piezoelectric layer made of lithium tantalate in an example.

FIG. 11A shows the temperature coefficient of frequency of the composite substrate of the comparative example.

FIG. 11B shows the temperature coefficient of frequency of the composite substrate of the example.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “upper,” “on,” “above,” “over,” and the like may be used throughout the disclosure while making reference to the features as illustrated in the drawings. The features may be oriented differently (e.g., rotated 90 degrees or at other orientations) and the spatially relative terms used herein may be interpreted accordingly.

FIG. 2 illustrates a conventional temperature compensated surface acoustic wave (TC-SAW) filter including a piezoelectric layer 10, a base layer 20 and a fork-finger transducer 30. The piezoelectric layer 10 and the base layer 20 corporately form a composite substrate.

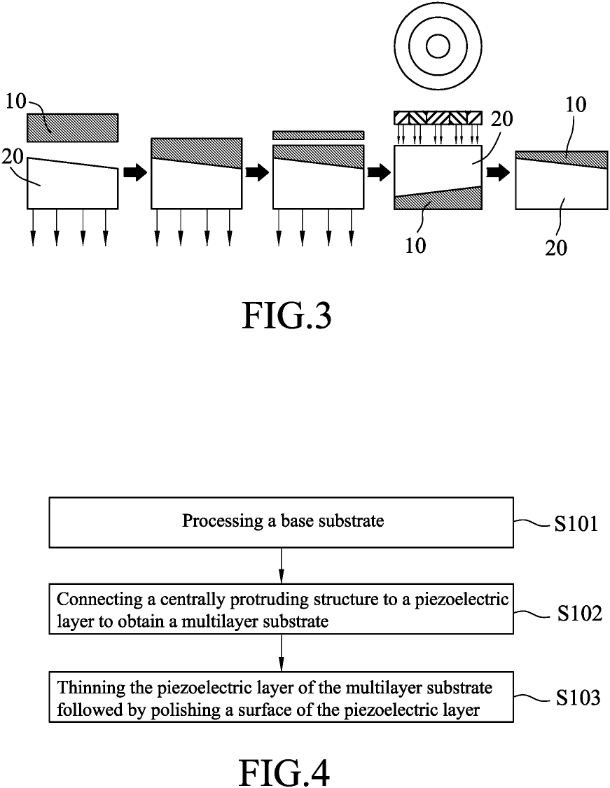

FIG. 3 illustrates a method for making the composite substrate of the conventional TC-SAW filter including the following consecutive steps: (i) separately forming the base layer 20 and the piezoelectric layer 10; (ii) bonding the base layer 20 to the piezoelectric layer 10 at room temperature; (iii) thinning the piezoelectric layer 10; (iv) polishing the base layer 20 using an adjustable air cushion polishing machine so that the base layer 20 has a desired thickness suitable for subsequent production steps; and (v) obtaining the composite substrate of the conventional TC-SAW filter.

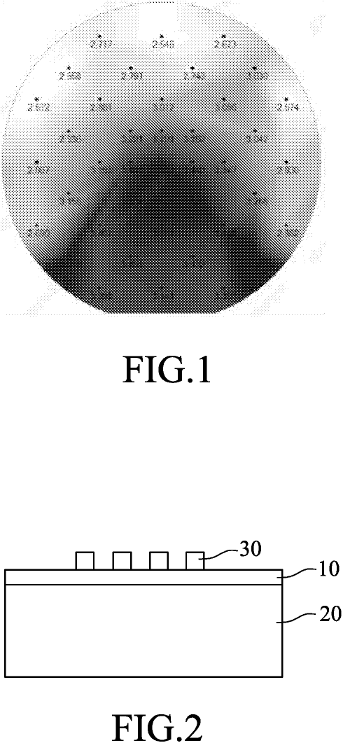

In the composite substrate made by the aforesaid method, a maximum thickness between upper and lower surfaces of the composite substrate is greater than a minimum thickness between the upper and lower surfaces of the composite substrate by an amount of over 1 µm. FIG. 1 illustrates a thickness distribution of the piezoelectric layer 10 that is made of lithium tantalate (LiTaO₃) and that is made through the aforesaid method shown in FIG. 3. As shown in FIG. 1, the piezoelectric layer 10 is 2.54 µm thick at a thinnest point and 3.51 µm thick at a thickest point. The target thickness of the piezoelectric layer 10 is 3 µm. However, the actual thickness of the piezoelectric layer 10 is in a range of 2.54 µm to 3.51 µm. The minimum and maximum thickness values (2.54 µm and 3.51 µm) of the piezoelectric layer 10 are respectively 84.7% and 117% of the target thickness (3 µm) and differ from the target thickness by 15.3% and 17%, respectively. That is to say, a thickness variation of the piezoelectric layer 10 is in a range of 15.3% to 17%. Therefore, the thickness variation is more than 15%. This indicates that the piezoelectric layer 10 has a significant thickness nonuniformity in view of a requirement for a thickness variation smaller than 10%.

This disclosure provides a method for making a composite substrate of a filter. A piezoelectric layer 200 (which will be described hereinafter) of the composite substrate of the filter has a thickness variation smaller than 10%.

Referring to FIGS. 4, 5 and 6, the method for making a first embodiment of the composite substrate of the filter according to the present disclosure includes the following consecutive steps S101 to S103.

In step S101, the base substrate 100 is processed to form a centrally protruding structure S having a height that decreases in a radially outward direction from a center of the base substrate 100 to an outer periphery of the base substrate 100. The base substrate 100 has a first side 100a and a second side 100b opposite to the first side 100a. The first side 100a of the base substrate 100 has the centrally protruding structure S.

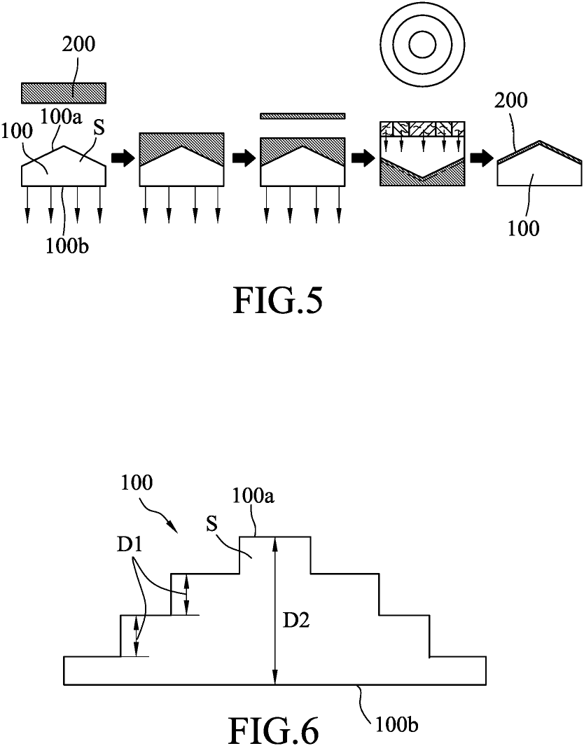

The centrally protruding structure S may be one of a stepped structure (see FIG. 6) and a non-stepped structure (see FIG. 5). The stepped structure may have at least two concentric step portions that are disposed one on the other. A highest one of the at least two concentric step portions is at the center of the base substrate 100. A lower one of the at least two concentric step portions is larger in width than a higher one of the at least two concentric step portions. The non-stepped structure may have a tapering surface that tapers from the outer periphery of the base substrate 100 to the center of the base substrate 100. In this embodiment, the centrally protruding structure S is the stepped structure and has four concentric step portions, all of which are cylindrical as shown in FIG. 6.

In certain embodiments, step S101 includes sub-steps (i) to (iv). In sub-step (i), pre-thinning is performed to pre-thin the base substrate 100 before the base substrate 100 is formed into the centrally protruding structure S so that the base substrate 100 has a predetermined thickness before the centrally protruding structure S is formed. The pre-thinning is optional and may be dispensed with in other embodiments, in which the base substrate 100 is selected from those having a predetermined thickness. The thickness of the base substrate 100 is a maximum height of the centrally protruding structure S. As shown in FIG. 6, the thickness D2 of the base substrate 100 is the maximum height of the centrally protruding structure S.

In sub-step (ii), the first side 100a of the base substrate 100 is arranged to face downward, and then a thinning step is performed on the first side 100a by polishing the base substrate 100 in a radially inward direction from the outer periphery of the base substrate 100 toward the center of the base substrate 100 in such a manner that a central portion at the center of the base substrate 100 is not polished and a circumferential portion surrounding the central portion is removed to expose a lowered circumferential surface. As a result, a highest one of the concentric step portions is formed at the first side 100a and at the center of the base substrate 100.

The thinning step may be conducted using a grinding wheel that has a grain size of 2000# to 6000#. An angle between a central axis of the grinding wheel and a central axis of the base substrate 100 ranges from 0.5° to 2°. In the thinning step, a thickness of a sacrificial layer that is removed from the first side 100a of the base substrate 100 is controlled to range from 4 µm to 10 µm.

In sub-step (iii), the thinning step is repeated by polishing the lowered circumferential surface which is exposed in such a manner that a central portion below the highest concentric step portion is not polished and an additional circumferential portion is removed to expose an additional circumferential surface to form a lower one of the concentric step portions. The thinning step is repeated three times to form three lower concentric step portions after the highest concentric step portion is formed. FIG. 6 also shows a height difference D1 between two adjacent concentric step portions, and a radial dimension of each concentric step portion from a central axis of the base substrate 100.

After sub-step (iii), the centrally protruding structure S is symmetrical with respect to the central axis of the base substrate 100, and the base substrate 100 has a total thickness variation (TTV) smaller than 1.5 µm.

In sub-step (iv), the first side 100a of the base substrate 100 and the second side 100b of the base substrate 100 opposite to the first side 100a are polished, so that the TTV of the base substrate 100 is smaller than 1 µm.

In certain embodiments, sub-step (iv) is conducted using a double side polish machine that includes an upper plate, a sun gear, and a lower plate. Specifically, the upper plate has a first polishing pad for polishing the first side 100a of the base substrate 100, and the lower plate has a second polishing pad for polishing the second side 100b of the base substrate 100.

The upper plate has a rotating speed ranging from 15 rpm/min to 25 rpm/min. The sun gear has a rotating speed ranging from 15 rpm/min to 25 rpm/min. The lower plate has a rotating speed ranging from 30 rpm/min to 50 rpm/min. A polishing pressure of the double side polishing machine ranges from 60 g/cm³ to 200 g/min³.

By virtue of polishing the first side 100a and the second side 100b of the base substrate 100, a TTV of the base substrate 100 might be reduced.

After performing sub-steps (i) to (iv) of step S101, a thickness difference between two concentric step portions is smaller than 0.3 µm, and the base substrate 100 has a maximum thickness smaller than 1 µm.

The base substrate 100 may be made of one of spinel, polycrystalline sapphire, monocrystalline sapphire, high resistance silicon, silicon carbide (SiC), aluminum nitride (AIN), and quartz.

In step S102, the first side 100a of the base substrate 100 having the centrally protruding structure S is connected to the piezoelectric layer 200 so as to obtain a multilayer substrate.

The piezoelectric layer 200 may be formed from a piezoelectric chip. In certain embodiments, the piezoelectric chip may have an initial thickness of 150 µm.

In step S103, the piezoelectric layer 200 of the multilayer substrate is thinned to a predetermined thickness, followed by polishing a surface of the piezoelectric layer 200.

In this step, the piezoelectric layer 200 of the multilayer substrate is thinned using a thinning machine so as to have a thickness ranging from 10 µm to 20 µm, and is then polished using the adjustable air cushion polishing machine so as to have a thickness smaller than 5 µm.

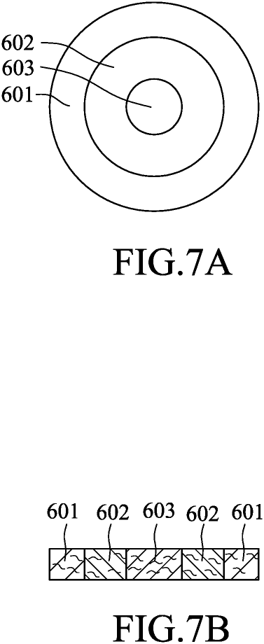

FIGS. 7A and 7B illustrate three polishing pad regions 601, 602, 603 of the adjustable air cushion polishing machine. The three polishing pad regions 601, 602, 603 of the adjustable air cushion polishing machine are distributed in a concentric manner and may be respectively provided with different polishing pressure, so as to realize the polishing of the piezoelectric layer 200.

The disclosure will be further described by way of the following examples. However, it should be understood that the following examples are solely intended for the purpose of illustration and should not be construed as limiting the disclosure in practice.

Comparative example:

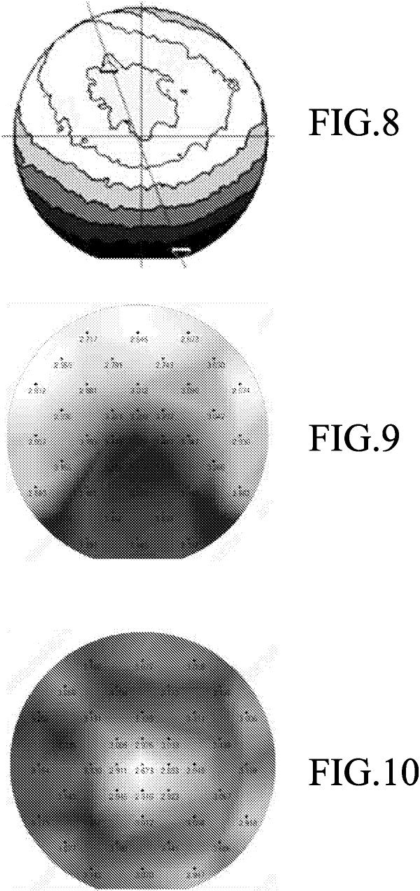

The base substrate is a sapphire substrate that is processed through a traditional way. The morphology of the base substrate is measured using NIDEK (FT-900). The measurement result shows a TTV of the base substrate is 1.19 µm, and the base substrate exhibits a non-concentric morphology as shown in FIG. 8. Afterwards, the base substrate is connected to a piezoelectric layer (a lithium tantalate (LT) chip) under high vacuum and at room temperature, and then the piezoelectric layer is thinned to a thickness of 4.5 µm using the thinning machine, followed by being polished to a thickness of 3.0 µm, so as to obtain a composite substrate of the comparative example. After polishing of the piezoelectric layer, the thickness of the piezoelectric layer is measured using Filmetrics (F-54). FIG. 9 illustrates a thickness distribution of the piezoelectric layer of the comparative example after being polished. It can be seen that the piezoelectric layer of the comparative example has a thickness variation of about 35.3%.

A method for making the composite substrate of the comparative example is similar to the aforesaid method for making the composite substrate of the conventional TC-SAW filter shown in FIG. 3. In the comparative example, the base substrate has an eccentric morphology that can not be changed using the adjustable air cushion polishing machine, and the piezoelectric layer of the composite substrate has an uneven thickness.

### EXAMPLE

A common sapphire substrate is used and is processed through the processing sub-steps (i) to (iv) of step S101. When the sapphire substrate is thinned, a removed amount of a thickness of the sapphire substrate depends on a TTV of the sapphire substrate which has not been processed. For example, before the sapphire substrate is thinned, the TTV of the sapphire substrate is 9.0 µm, and the amount of the thickness of the sapphire substrate to be removed should be larger than 9.0 µm, so as to enhance or reduce the TTV of the sapphire substrate. After the sapphire substrate is thinned, a surface morphology of the sapphire substrate is measured using the NIDEK (FT-900). The measurement result shows the TTV of the sapphire substrate is 1.01 µm and the sapphire substrate has a concentric morphology.

The sapphire substrate is connected to a piezoelectric layer made of lithium tantalate (LiTaO₃) under high vacuum and at room temperature, and then the piezoelectric layer is thinned to a thickness of 4.5 µm using the thinning machine followed by being polished to a thickness of 3.0 µm, so as to obtain a composite substrate of the example. After polishing of the piezoelectric layer, the thickness of the piezoelectric layer is measured using Filmetrics (F-54). FIG. 10 illustrates a thickness distribution of the piezoelectric layer of the example after being polished. It can be seen that the piezoelectric layer of the example has a thickness variation of about 9.2%.

In this disclosure, by virtue of the composite substrate of the filter made through the aforesaid method shown in FIG. 4, the thickness variation of the piezoelectric layer 200 is smaller than 10%. The reason for the piezoelectric layer 200 to have such thickness variation is that the first side 100a of the base substrate 100 that is bonded with the piezoelectric layer 200 has the centrally protruding structure S in which the concentric step portions exhibit symmetry with respect to the central axis of the base substrate 100. When the piezoelectric layer 200 is bonded to the base substrate 100 and thinned, stresses from the piezoelectric layer 200 to the base substrate 100 are mainly concentrated on the central cylindrical area of the centrally protruding structure S and are distributed to the surrounding areas of the centrally protruding structure S in a relatively uniform manner. This can reduce resisting forces against thinning and polishing actions and facilitate obtaining a relatively uniform thickness of the piezoelectric layer 200. In this embodiment, the TTV of the piezoelectric layer 200 is smaller than 10%. In certain embodiments, the TTV of the piezoelectric layer 200 may be smaller than 5%.

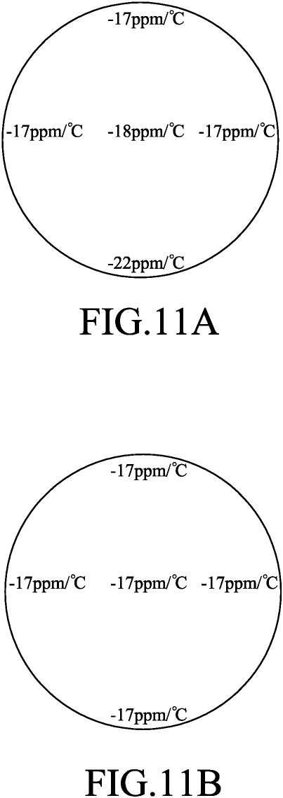

FIGS. 11A and 11B respectively illustrate temperature coefficient of frequency (TCF) distributions in the comparative example and example. As shown in FIG. 11B, in the example, the composite substrate has a uniform TCF distribution and the TCF value thereof is 17 ppm/°C in all area. In addition, the composite substrate of the example has a better TCF and exhibits good performance at 900 MHz and 1800 MHz.

In this disclosure, the composite substrate has the following properties.

1. The thickness variation of the piezoelectric layer 200 ranges from 4% to 10%, and the TTV of the piezoelectric layer 200 is smaller than 0.3 µm (i.e., the maximum thickness minus the minimum thickness is smaller than 0.3 µm).

2. The composite substrate has a uniform TCF distribution, and a difference between a maximum TCF value and a minimum TCF value is smaller than 2 ppm/°C.

3. The filter that includes the composite substrate has a better frequency drift. The frequency drift at 900 MHz may be controlled to be smaller than 500 ppm, and at 1800 MHz may be controlled to be smaller than 1000 ppm.

By virtue of the base substrate 100 including the centrally protruding structure S, difficulties encountered in polishing the piezoelectric layer 200 can be obviously reduced, so that the piezoelectric layer 200 has a uniform thickness and an enhanced uniformity. A good yield of filter chips can be realized when the piezoelectric layer 200 is used in the filter chips.

This disclosure also provides a composite substrate of a filter, which is made by the aforesaid method shown in FIG. 4.

This disclosure also provides a TC-SAW filter including the aforesaid composite substrate of the filter, and a fork-finger transducer disposed on the aforesaid composite substrate of the filter, wherein the piezoelectric layer 200 of the composite substrate of the filter has a thickness variation smaller than 10%. In the TC-SAW filter, the composite substrate includes the base substrate 100 and the piezoelectric layer 200, and the fork-finger transducer is disposed on the piezoelectric layer 200.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method for making a composite substrate of a filter, comprising the steps of:
a) processing a base substrate to form a centrally protruding structure having a height that decreases in a radially outward direction from a center of the base substrate to an outer periphery of the base substrate;
b) connecting a first side of the base substrate having the centrally protruding structure to a piezoelectric layer so as to obtain a multilayer substrate; and
c) thinning the piezoelectric layer of the multilayer substrate, followed by polishing a surface of the piezoelectric layer.

2. The method as claimed in claim 1, wherein the centrally protruding structure is one of a stepped structure and a non-stepped structure, the stepped structure having at least two concentric step portions that are disposed one on the other, a highest one of the at least two concentric step portions being at the center of the base substrate, a lower one of the at least two concentric step portions being larger in width than a higher one of the at least two concentric step portions, the non-stepped structure having a tapering surface that tapers from the outer periphery of the base substrate to the center of the base substrate.

3. The method as claimed in claim 1, wherein step a) includes optionally pre-thinning the base substrate before the base substrate is formed into the centrally protruding structure so that the base substrate has a predetermined thickness before the centrally protruding structure is formed.

4. The method as claimed in claim 2, wherein the centrally protruding structure is the stepped structure, and the step a) includes:
a-1) facing downward the first side of the base substrate that has a predetermined thickness;
a-2) performing a thinning step on the first side by polishing the base substrate in a radially inward direction from the outer periphery of the base substrate toward the center of the base substrate in such a manner that a central portion of the base substrate is not polished and a circumferential portion surrounding the central portion is removed to expose a lowered circumferential surface, whereby the highest one of the at least two concentric step portions is formed;
a-3) repeating the thinning step by polishing the lowered circumferential surface in the radially inward direction from the outer periphery of the base substrate in such a manner that a central portion below the highest one of the at least two concentric step portions is not polished and an additional circumferential portion is removed to expose an additional circumferential surface, whereby a lower one of the at least two concentric step portions is formed; and
a-4) polishing the first side of the base substrate and a second side of the base substrate opposite to the first side.

5. The method as claimed in claim 4, wherein the thinning step is conducted using a grinding wheel that has a grain size of 2000# to 6000#, an angle between a central axis of the grinding wheel and a central axis of the base substrate ranging from 0.5° to 2°.

6. The method as claimed in claim 4, wherein, in the thinning step, a thickness of a sacrificial layer that is removed from the first side of the base substrate is controlled to range from 4 µm to 10 µm.

7. The method as claimed in claim 4, wherein sub-step a-4) is conducted using a double side polish machine that includes an upper plate, a sun gear, and a lower plate, the upper plate having a first polishing pad for polishing the first side of the base substrate, the lower plate having a second polishing pad for polishing the second side of the base substrate, the upper plate having a rotating speed that ranges from 15 rpm/min to 25 rpm/min, the sun gear having a rotating speed that ranges from 15 rpm/min to 25 rpm/min, the lower plate having a rotating speed that ranges from 30 rpm/min to 50 rpm/min, a polishing pressure of the double side polishing machine ranging from 60 g/cm³ to 200 g/min³.

8. The method as claimed in claim 1, wherein after step c), the multilayer substrate has a thickness variation ranging from 4% to 10%.

9. The method as claimed in claim 4, wherein in step a), a thickness difference between the at least two concentric step portions is smaller than 0.3 µm, and the centrally protruding structure has a maximum thickness smaller than 1 µm.

10. The method as claimed in claim 1, wherein in step c), the piezoelectric layer (200) of the multilayer substrate is thinned using a thinning machine so as to have a thickness ranging from 10 µm to 20 µm, and the piezoelectric layer is polished using an adjustable air cushion polishing machine so as to have a thickness smaller than 5 µm.

11. The method as claimed in claim 1, wherein in step a), the base substrate is made of one of spinel, polycrystalline sapphire, monocrystalline sapphire, high resistance silicon, silicon carbide, aluminum nitride, and quartz.

12. A composite substrate of a filter, which is manufactured by the method as claimed in claim 1.

13. A temperature compensated surface acoustic wave (TC-SAW) filter comprising the composite substrate of the filter as claimed in claim 12, and a fork-finger transducer disposed on said composite substrate of said filter, wherein said piezoelectric layer of said composite substrate of said filter has a thickness variation smaller than 10%.
